(19) United States
(12) Patent Application Publication
(10) Pub. No.: US 2001/0045262 A1
(43) Pub. Date: Nov. 29, 2001

(54) Chemical vapor deposition chamber

(75) Inventors: Rudolf Gujer, Saratoga, CA (US); Thomas K. Cho, Palo Alto, CA (US); Tetsuya Ishikawa, Santa Clara, CA (US)

Correspondence Address: Patent Counsel, Applied Materials, Inc., 3050 Bowers Avenue, P.O. Box 450-A, Santa Clara, CA, 95052, US

(73) Assignee: Applied Materials, Inc.

(21) Appl. No.: 09/797,211

(22) Filed: Feb. 28, 2001

Related U.S. Application Data
(60) Provisional application No. 60/185,283, filed on Feb. 28, 2000.

(51) Int. Cl. C23C 16/00; C23F 1/02

(52) U.S. Cl. 156/345; 118/728

(57) ABSTRACT

A semiconductor wafer-processing chamber comprises a substrate support platform having a centrally disposed recess and a substrate support assembly disposed over the centrally disposed recess of the support platform. At least one platform arm extends radially from the substrate support platform to a sidewall of said processing chamber. A pair of fluid line conduits, a RF cable conduit, a temperature probe conduit, and a backside gas supply line conduit having a pair of fluid lines, a RF cable, a temperature probe cable, and a backside gas supply line respectively, are disposed diagonally to define a negative slope through the at least one platform arm and communicate with the centrally disposed recess. The centrally disposed recess serves as a sump for drainage of unwanted fluids and contaminants through such conduits.

### CROSS REFERENCE

This application claims benefit of U.S. Provisional Application Ser. No. 60/185,283, filed Feb. 28, 2000, which is hereby incorporated by reference in its entirety.

### BACKGROUND OF THE DISCLOSURE

1. Field of Invention

The present invention relates generally to apparatus for processing semiconductor wafers. More specifically, the invention relates to an apparatus for depositing material on a semiconductor wafer using a chemical vapor deposition process.

2. Description of the Background Art

Integrated circuits have evolved into complex devices that include millions of transistors, capacitors and resistors on a single chip. The evolution of chip designs continually requires faster circuitry and greater circuit density. As the demand for integrated circuits continue to rise, chip manufactures have demanded semiconductor process tooling having increased wafer throughput and greater product yield. To meet this increase in throughput, tooling has been developed to process larger diameter wafers, for example, wafers having diameters of 300 mm.

Processing chambers generally capable of processing 300 mm wafers typically have greater internal volume than chambers designed to process smaller diameter wafers. The greater internal volume correspondingly requires pumping equipment having higher capacity in order to achieve and maintain the low processing pressures commonly utilized during deposition and other integrated circuit fabrication processes. Higher capacity pumps are generally more expensive and consume more energy during operation than pumps that have smaller flow capacity.

One method for reducing the pump capacity requirements is to maximize the conductance of the pumping chamber. The conductance, which is generally the inverse of flow resistance, can be increased by providing large ports for the gases to move through the chamber, as well as by placing the pump close to the chamber. However, the proximity of the pumps to the processing chamber is typically limited by the space required below a wafer support surface to route heat transfer fluids, electrical connections, sensor leads, lift-pin actuation mechanisms, and the like. In addition, an o-ring is typically disposed between the pump and the chamber to seal the two components together; thus allowing for the formation of a vacuum therebetween. A problem observed has been the deterioration of the o-ring, which then requires time-consuming maintenance downtime of the processing chamber.

In addition, processing chambers for 200 mm wafers comprise substrate support assemblies. Typically, each substrate support assembly has a RF cable comprised of multiple conductors coupled together, which as a whole, provide RF biasing to the substrate support assembly. One problem with the multiple conductor RF cable is that fusing amongst the multiple conductors may occur. Another problem is that the RF cable is proximate one or more temperature control fluid lines. The temperature control fluid lines provide a cooling fluid to a cooling plate in the substrate support assembly. It has been observed that the fluid lines in a substrate support surface may leak, thereby risking damage to the RF cable, electrical short circuiting of the RF power source, and the substrate support assembly.

Therefore, there is a need in the art for a deposition process chamber that minimizes the distance of the pump from the chamber. Furthermore, there is a need to protect the internal components in the substrate support assembly from possible collateral damage caused by the failure of another component. Moreover, it would be desirable for such a system to minimize particulate contamination, the number of components, maximize seal life, and provide ease of serviceability.

### SUMMARY OF INVENTION

The disadvantages associated with the prior art are overcome by the present invention of a semiconductor wafer-processing chamber. The chamber comprises a substrate support platform having a centrally disposed recess and a substrate support assembly coupled over the centrally disposed recess of the support platform. At least one platform arm extends radially from the substrate support platform to a sidewall of said processing chamber.

A pair of fluid line conduits, a RF cable conduit, and a backside gas supply line conduit having a pair of fluid lines, a RF cable, and a backside gas supply line respectively, are disposed diagonally to define a negative slope through the at least one platform arm, and communicate with the centrally disposed recess. As such, the centrally disposed recess facilitates coupling these support platform components. Furthermore, the centrally disposed recess and conduits that facilitate the support platform components serve as a sump for drainage of unwanted fluids and contaminants.

### BRIEF DESCRIPTION OF DRAWINGS

The teachings of the present invention can be readily understood by considering the following detailed description in conjunction with the accompanying drawings, in which:

FIG. 1 depicts a cross sectional view of a semiconductor processing system of the present invention;

FIG. 2 depicts a cross sectional view of a chamber body taken along section line 2-2;

FIG. 3 depicts a partial cross sectional view of the chamber body having a centrally disposed recess taken along section line 3-3 of FIG. 2;

FIG. 4 depicts a cross sectional view of the chamber body having a substrate support assembly taken along section line 4-4 of FIG. 2;

FIG. 5 depicts a cross sectional view of the chamber body having a temperature probe cable taken along section line 5-5 of FIG. 2;

FIG. 6 depicts a cross sectional view of the chamber body having a fluid supply line conduit and a backside gas supply line taken along section line 6-6 of FIG. 2;

FIG. 7 depicts a cross sectional view of the chamber body having a RF cable taken along section line 7-7 of FIG. 2;

FIG. 8 depicts a bottom perspective view of an electrostatic chuck and the RF cable; and

FIG. 9 depicts a cross sectional view of a terminal assembly of the RF cable of FIGS. 7 and 8.

To facilitate understanding, identical reference numerals have been used, where possible, to designate identical element that are common to the figures.

### DETAIL DESCRIPTION OF INVENTION

The present invention generally provides an apparatus for processing a semiconductor substrate. The invention is illustratively described below as a chemical vapor deposition system, such as an ULTIMA® High Density Plasma Chemical Vapor Deposition (HDP-CVD) system, available from Applied Materials, Inc. of Santa Clara, Calif. However, it should be understood that the invention may be incorporated into other chamber configurations such as physical vapor deposition chambers, etch chambers, ion implant chambers, and other semiconductor processing chambers.

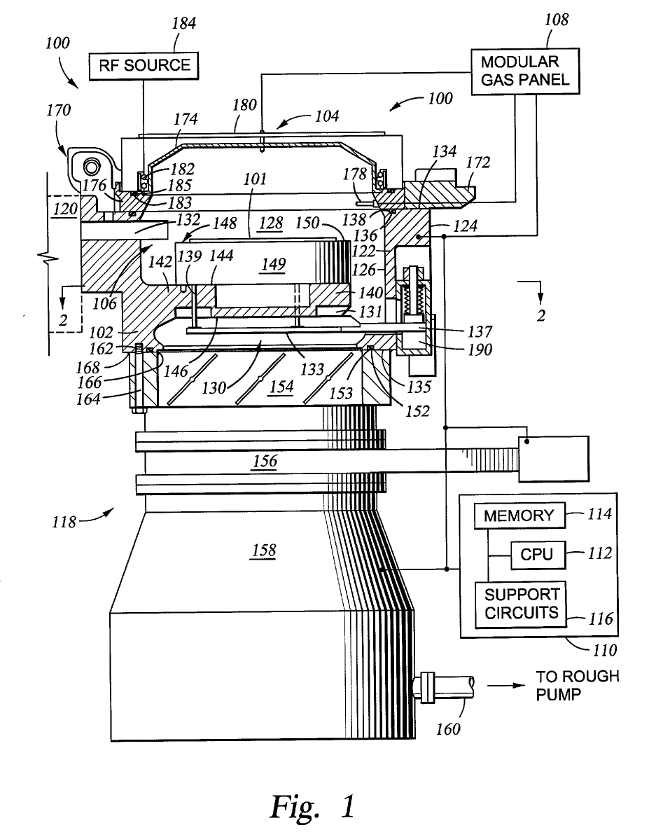

FIG. 1 depicts a partial cross section of a semiconductor processing system 100 of the present invention. In particular, FIG. 1 depicts an illustrative HDP-CVD chamber system (system) 100 that generally comprises a chamber body 102 and a lid assembly 104 that defines an evacuable chamber 106 for carrying out substrate processing. The system 100 may be one of a number of substrate processing systems that are coupled to a processing platform 120 (only partially viewable) such as a CENTURA® processing platform, available from Applied Materials, Inc. The system 100 also includes a pumping stack 118, a modular gas panel 108 and a controller 110. The controller 110 has a central processing unit (CPU) 112, a memory 114, and support circuits 116. The controller 110 is coupled to the various components of the system 100 to facilitate control of the deposition process.

The chamber body 102 is typically a unitary, machined structure fabricated from a rigid block of material such as aluminum. The chamber body 102 has a plurality of sidewalls 122 having a substantially rectangular outside surface 124 and an annular, inner surface 126 that defines a processing region 128. The annular, inner surface 126 that defines processing region 128 generally tapers to further define an exhaust passage 130. Furthermore, at least one sidewall 122 is electrically grounded (not shown). The chamber body 102 contains a substrate entry port 132 that is selectively sealed by a slit valve (not shown) disposed in the processing platform 120.

A substrate support platform 140 is coupled to the sidewall 122 by one or more support arms 142 (only one shown). The support platform 140 comprises a first surface 144 for supporting a support assembly 148 and a second surface 146 that faces the exhaust passage 130. A substantially C-shaped slot 131 circumscribes the second surface 146 to provide room for a lift-pin arm 133 having a distal end 137, which is coupled to an actuator assembly 190. The lift-pin arm 133 actuates a plurality of lift-pins 139 during wafer processing. For a detailed understanding of the C-shaped slot 131, lift-pin arm 133, lift-pins 139, and actuator assembly 190, the reader should refer to the drawings and the detailed description in commonly assigned U.S. Application titled “Semiconductor Wafer Support Lift-pin Assembly”, authored by Gujer et al., Attorney Docket No. 4352/PDD/KPU3/JW, filed concurrently with this application, and incorporated herein by reference.

The substrate support assembly 148 is disposed on the first surface 144 of the support platform 140. The substrate support assembly 148 generally comprises a substrate support 150 and a cathode base 149. The substrate support 150 may be a susceptor, a heater, ceramic body, or electrostatic chuck on which the substrate or wafer 101 is placed during processing. For a detailed understanding of the operation of an electrostatic chuck during wafer processing, the reader should refer to the drawings and the detailed description in commonly assigned U.S. Pat. No. 5,350,479, issued Sep. 27, 1994, and incorporated herein by reference. That patent teaches an electrostatic chuck manufactured by Applied Materials, Inc. of Santa Clara, Calif.

A first surface 134 of the chamber body 102 defines a generally flat landing area on which the lid assembly 104 is supported. An o-ring groove 136 is formed in the first surface 134 of the sidewall 122 to receive an o-ring 138 that forms a gas-tight seal between the chamber body 102 and the lid assembly 104. Typically, the o-ring 138 is fabricated from a fluoropolymer or other material compatible with the processing environment such as CHEMREZ™.

The lid assembly 104 generally includes a lid 172, an energy transmitting dome 174 and a gas distribution ring 176. The lid 172 is coupled to the dome 174 and gas distribution ring 176. The lid 172 is typically fabricated from aluminum. The dome 174 is made of dielectric material that is transmissive to RF energy, for example, a ceramic such as aluminum oxide (Al₂O₃). For a detailed understanding of the lid assembly 104, the reader should refer to the drawings and the detailed description in commonly assigned U.S. Application titled “Chemical Vapor Deposition Chamber Lid Assembly”, authored by Pang et al., Attorney Docket No. 4352-5/PDD/KPU3/JW, filed concurrently with this application, and incorporated herein by reference. That patent teaches a lid having a dual pivot hinge assembly, which is manufactured by Applied Materials, Inc. of Santa Clara, Calif. At least one antenna or coil 182 is wound external to the dielectric dome 174. The coil 182 is powered by a variable frequency RF power source 184. The RF power source 184 includes a RF matching network to transfer power to plasma generated in the processing region 128. The temperature of the dome 174 is regulated during the various process cycles, i.e., deposition cycle and cleaning cycle. Typically, the dome 174 is heated during cleaning cycles and cooled during processing.

The gas distribution ring 176 is disposed between the dome 174 and the chamber body 102. O-ring grooves 183 are formed in the top of the gas distribution ring 176 to receive an o-ring 185 to seal the dome 174 and the top of the gas distribution ring 176. The gas distribution ring 176 typically comprises an annular ring made of aluminum or other suitable material having a plurality of ports formed therein for receiving nozzles 178 that are in communication the gas panel 108. The gas panel 108 may alternately be coupled to the chamber 106 via a showerhead or second nozzle 180 disposed beneath the dome 174. Optionally, both a showerhead and gas distribution ring 176 may be used in conjunction with each other. The gas panel 108 provides process and other gases to the chamber 106.

Opposite the first surface 134 of the chamber body 102 upon which the lid assembly 104 is disposed, is a second surface 135 of the sidewall 122. Disposed centrally in the second surface 135 is the exhaust passage 130. The second surface 135 defines a generally flat landing area that abuts the pumping stack 118, which communicates with the exhaust passage 130. The pumping stack 118 includes a throttle valve assembly 154, a gate valve 156 and a turbomolecular pump 158. The pumping stack 118 is mounted to the exhaust passage 130 of the chamber body 102 to provide pressure control within the system 100. Typically, the throttle valve assembly 154 is coupled to the chamber body 102, with the gate valve 156 disposed between the turbomolecular pump 158 and the throttle valve assembly 154. The throttle valve assembly 154 is mounted to the chamber body 102 via four mounting bolts 164, one of which is shown threaded into a threading mounting hole 162 disposed in the second surface 135 of the chamber body 102. An o-ring 152 or other vacuum seal is disposed in an o-ring groove 153 formed in the second surface 135 of the sidewall 122.

To reduce the periodic need to disassemble the throttle valve assembly 154 from the chamber body 102 to perform maintenance on the o-ring 152, the throttle valve assembly 154 is optionally welded to the chamber body 102. For example, an inside joint between the throttle valve assembly 154 and chamber body 102 includes a continuous electron beam weld 166 that provides a gas-tight seam between the throttle valve assembly 154 and chamber body 102. To provide structural rigidity and minimize the load upon the electron beam weld 166, an outside joint between the throttle valve assembly 154 and the chamber body 102 includes a plurality of stitch or tack welds 168. As the tack weld 168 prevents the electron beam weld 166 from excessive stress, the probability of the electron beam weld 166 developing a leak is minimized.

A line 160 couples the turbomolecular pump 158 to a remote mainframe or roughing pump (not shown). The roughing pump evacuates the chamber 106 to a vacuum level within the operational range of the turbomolecular pump 158. Once the chamber 106 has been pumped down to the level wherein the turbomolecular pump 158 may operate, the turbomolecular pump 158 is activated to further reduce the chamber pressure to a processing vacuum level.

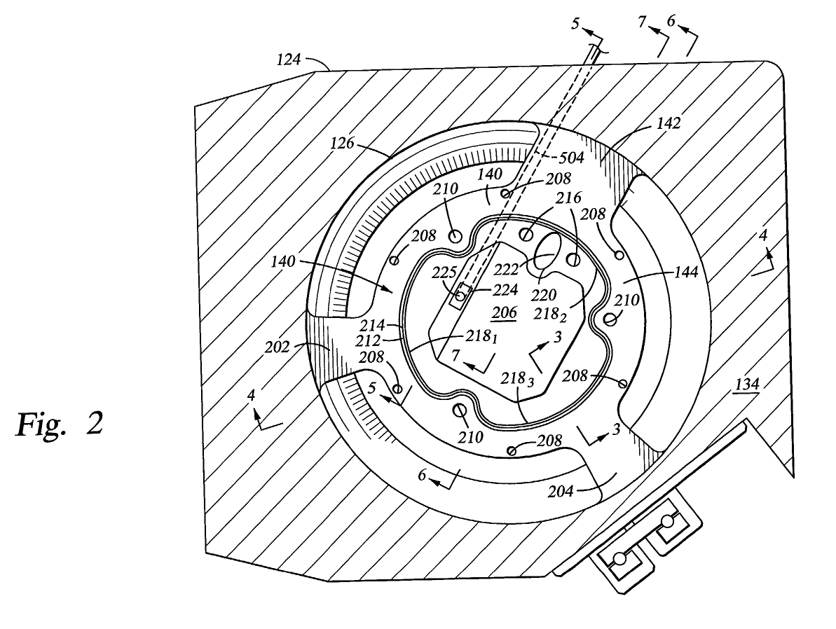

FIG. 2 depicts a cross sectional view of a chamber body 102 taken along section line 2-2. Referring to FIGS. 1 and 2 together, the substrate support platform 140 is coupled to the sidewall 122 by one or more support arms (i.e., a first support arm 142, a second support arm 202, and a third support arm 204). The support arms 142, 202, and 204 extend radially from the sidewall 122 to the support platform 140, positioning the support platform 140 in the center of the chamber 106.

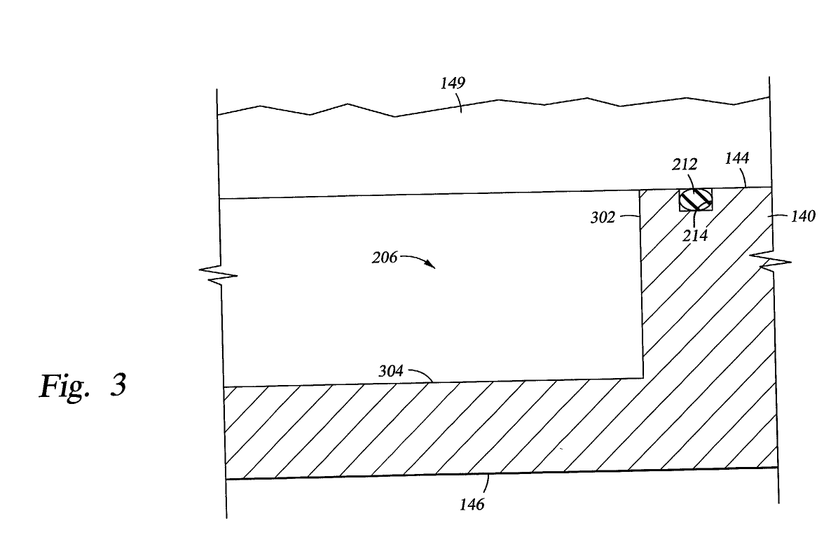

FIG. 3 depicts a partial cross sectional view of the chamber body 102 having a centrally disposed recess 206 taken along section line 3-3 of FIG. 2. Referring to FIGS. 2 and 3 together, the first surface 144 of the support platform 140 comprises the centrally disposed recess 206, which is defined by a plurality of walls 302 extending from the first surface 144 to a bottom 304. The first surface 144 additionally comprises a plurality of a threaded mounting holes 208 and a plurality of lift-pin holes 210. In one embodiment, the support platform 140 contains six mounting holes 208 and three lift-pin holes 210. The mounting holes 208 are typically blind holes while the lift-pin holes 210 generally extend through the support platform 140 such that a lower end of the lift-pin hole 210 exits the second surface 146 and is exposed to the exhaust passage 130.

A lobed o-ring 212 is disposed in a conforming o-ring groove 214 formed in the first surface 144. The lobed o-ring 212 is fabricated from a fluoropolymer or other material compatible with the processing environment such as CHEMREZ™. Generally, the lobed o-ring 214 provides a seal that separates the processing environment of the processing region 128 from the typically atmospheric environment of the recess 206. The lobed o-ring 212 generally passes radially inward of the lift-pin holes 210. The lobed o-ring 212 includes a plurality of lobes 218 (e.g., lobes 218₁, 218₂, and 218₃) that are disposed radially outward such that a greater area of the first surface 144 is isolated from the processing region 128. For example, one or more gas passages 216 may be disposed through the support platform 140 in the area of the first surface 144 bordered by the one of the lobes 218. Additionally, the area of the first surface 144 bordered by one of the lobes 218 provides space for a first end 220 of an RF conduit 222 to be disposed on the first surface 144, without requiring additional O-rings to isolate the RF conduit from the processing region 128. For a detailed understanding of the lobed o-rings, the reader should refer to the drawings and the detailed description in commonly assigned U.S. Application titled “Semiconductor Substrate Support Assembly Having Lobed O-Rings Therein”, authored by Gujer et al., Attorney Docket No. 4352-2/PDD/KPU3/JW, filed concurrently with this application, and incorporated herein by reference. That patent teaches a substrate support assembly 148 having a plurality of lobed O-rings provided therein, which is manufactured by Applied Materials, Inc. of Santa Clara, Calif.

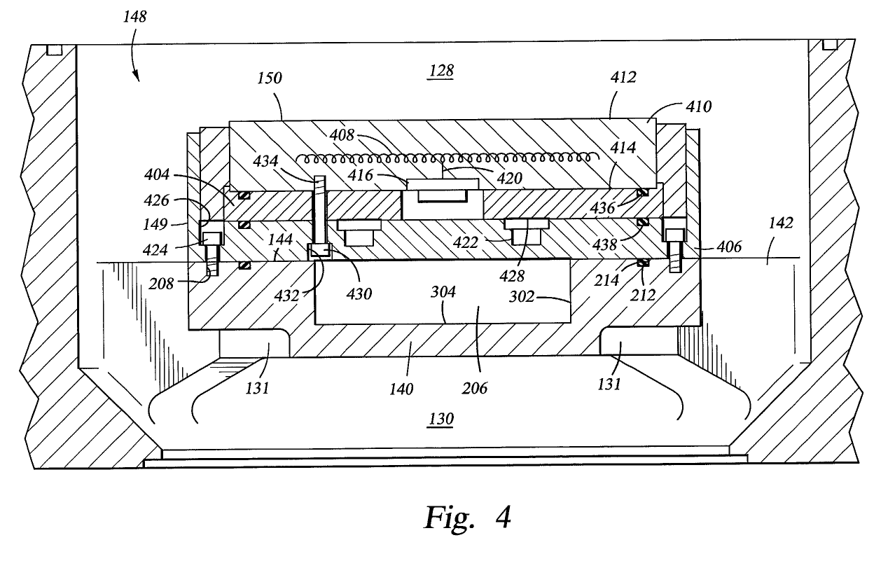

FIG. 4 depicts a cross sectional view of the chamber body 102 having a substrate support assembly 148 taken along section line 4-4 of FIG. 2. Specifically, the substrate support assembly 148 generally comprises a substrate support (shown as an electrostatic chuck 150), an insulative plate 404, and a cathode base 149. The substrate support 150 may be a susceptor, a heater, ceramic body, or electrostatic chuck on which the substrate or wafer 101 (not shown in FIG. 4) is placed during processing. The electrostatic chuck 150 generally comprises a ceramic body 410 having a wafer support surface 412 and an opposing second surface 414.

The electrostatic chuck 150 is provided with at least one chucking electrode 408. The chucking electrodes 408 are fabricated from a conductive material, (e.g., tungsten). The chucking electrodes 408 are disposed relatively close to the wafer support surface 412 of the electrostatic chuck 150. In this way, the chucking electrodes 408 provide the necessary electrostatic force to the backside of a wafer 101 to retain it on the electrostatic chuck 150. The chucking electrodes 408 may be in any configuration necessary to retain the wafer 101 upon the chuck 150. For example, the chucking electrodes 408 may be in a monopolar configuration, bipolar configuration, zoned chucking configuration or the like. The chucking electrodes 408 are also connected to a remote power source, such as a high voltage DC (HVDC) power supply (not shown). The chucking electrodes 408 are electrically coupled to a contact pad 416 disposed on the second surface 414 of the electrostatic chuck 150 via a conductive feedthrough 420. The contact pad 416 is then coupled to the HVDC power supply (not shown) to chuck the wafer 101. In one embodiment, the chucking electrodes 408 also serve as biasing electrodes. In particular, a RF power supply (not shown) is superimposed on the electrodes 408 to create a biasing voltage. However, preferably the cathode base 149 is directly coupled to the biasing RF power supply to bias the wafer.

The insulative plate 404 is disposed between the electrostatic chuck 150 and the cathode base 149. The insulative plate 404 is fabricated from a dielectric material such as ceramic, and generally includes a plurality of passages having various dimensions to permit access of different types of components between the electrostatic chuck 150 and support surface 412. The individual passages, o-rings, and reference numerals have been omitted for the sake of clarity.

The cathode base 149 may be fabricated from molybdenum, stainless steel, and the like. The cathode base 149 includes a substantially coil shaped cooling fluid channel 422 disposed there within and generally parallel to the first surface 144. The cooling fluid channel 422 typically is sealed using a cap 428 disposed over the fluid channel 422. The cooling fluid channel 422 is provided with a cooling fluid, such as water, from a pair of conduits (i.e. supply and return conduits (not shown)) coupled to a fluid source (not shown) external to the processing system 100.

The cathode base 149 is fastened to the support platform 140 utilizing a plurality of bolts 424 that pass through a corresponding hole 426 in the cathode base 149 and into the threaded mounting hole 208 disposed in the support platform 140. The support assembly 148 is secured together by threaded fasteners 430, one of which is shown. The threaded fastener 430 extends from a counter-bored hole 432 in the cathode base 149, passing through the insulative plate 404 and into a threaded hole 434 in the electrostatic chuck 150. A second lobed o-ring 436 and a third lobed o-ring 438, configured substantially identical to the lobed o-ring 212, are disposed respectively between the electrostatic chuck 150 and insulative plate 404, and insulative plate 404 and cathode base 149. Generally, each lobed o-ring 436, 438 reduces the number of o-rings required between the cathode base 149, insulative plate 404, and electrostatic chuck 150 as described above with reference to the lobed o-ring 212.

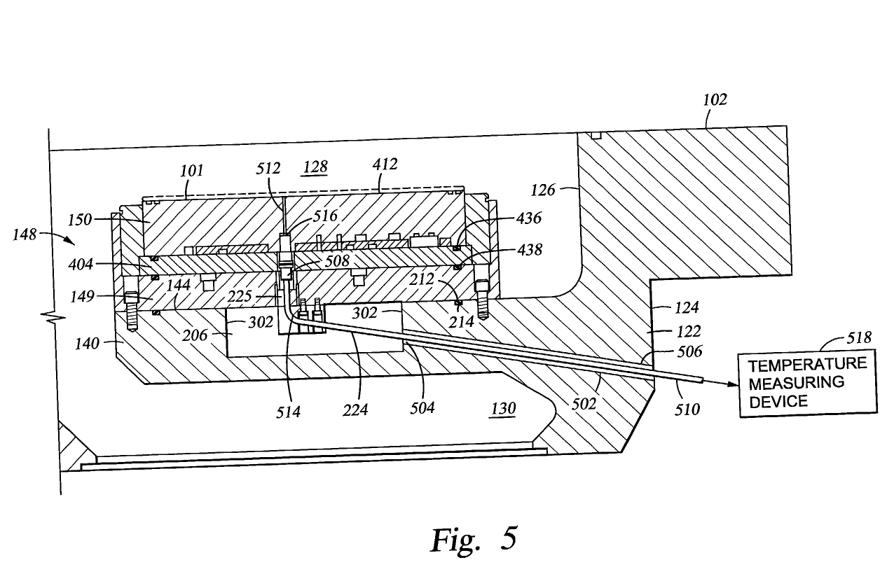

FIG. 5 depicts a cross sectional view of the chamber body 102 having a temperature probe cable 224 taken along section line 5-5 of FIG. 2. Specifically, a temperature probe cable conduit 502 has a first end 504 that is typically disposed in one of the plurality of walls 302 of the centrally disposed recess 206. A second end 506 of the temperature probe cable conduit 502 terminates at the outside surface 124 of the sidewall 122 of the chamber body 102 such that the conduit 502 passes through one of the support arms, for example, the first support arm 142. The first end 504 of the conduit 502 is positioned higher than the second end 506 such that the conduit 502 traverses diagonally and radially outward through the support arm 142. Preferably the temperature probe cable conduit 502 traverses with a negative slope through the support arm 142 at an angle less than 90°.

Extending through the cable conduit 502 is a wafer temperature probe cable 224 having a first end 514 coupled to a probe assembly 508 having a probe (i.e., sensor), such as a sapphire rod 512. The probe assembly 508 is disposed in a first probe channel 225 such that the probe assembly 508 is positioned radially within the inner area of the plurality of lobed o-rings 212, 436, and 438 of the substrate support assembly 148. The sapphire rod 512 extends through a second probe channel 516 such that an end of the sapphire rod faces the underside of a wafer when positioned upon the support surface 412 of the electrostatic chuck 150.

The temperature probe cable 224 extends through the central recess 206 and temperature probe cable conduit 502 where a second end 510 of the cable 224 is coupled to a device 518 capable of measuring wavelength intensities. In operation, light wavelengths are reflected from the underside of the wafer 101, back to the probe assembly 508, and carried via the cable 224 to the measuring device 518. Thereafter, measuring device 518 converts the wavelength intensities into temperature measurements representing the temperature of the wafer 101. The measuring device 518 then provides the controller 110 with temperature information used to maintain the temperature of the wafer 101 during processing. Typically, the controller 110 changes the temperature of the heat transfer fluid (e.g., water) circulated in the electrostatic chuck 150 to maintain the substrate 101 at a predetermined temperature. Alternatively, other heating and cooling methods, such as resistive heating, may be utilized to control the temperature of the wafer 101 during processing.

In this manner, the probe assembly 508 and first end 514 of the temperature probe cable 224 are isolated and protected from the processing environment. Furthermore, the conduit 502, in addition to facilitating housing the cable 224 through the chamber body 102, also provides a source for drainage of undesirable liquids or gasses, which may accumulate in the centrally disposed recess 206.

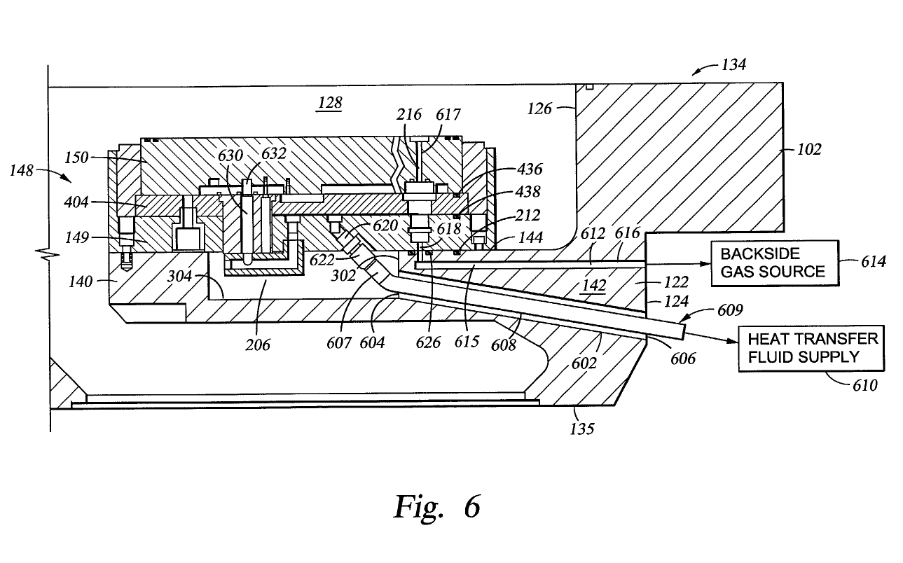

FIG. 6 depicts a cross sectional view of the chamber body having a fluid supply line conduit and a backside gas supply line taken along section line 6-6 of FIG. 2. Specifically, FIG. 6 depicts a first fluid supply line conduit 602 having a first end 604 that is typically disposed in one of the plurality of walls 302 of the recess 206. At least a portion of the first end 604 intersects or lies in the same plane as the bottom 304 of the recess 206. A second end 606 of the first fluid supply line conduit 602 terminates at the outside surface 124 of the sidewall 122 of the chamber body 102 such that the conduit 602 passes through one of the support arms, for example, the first support arm 142. Generally, the second end 606 is positioned closer to the second surface 135 of the chamber body 102 than the first end 604. The second fluid supply line conduit of the pair of fluid supply line conduits (not shown) is similarly configured and typically disposed adjacent to the first fluid supply line conduit 602. As such, the first and second fluid supply line conduits 602 traverse with a negative slope through the support arm 142 at an angle less than 90°.

A first fluid supply line 608 of a pair of fluid supply lines (only the first fluid supply line depicted in FIG. 6) is disposed within the first supply line conduit 602. The first fluid supply line 608 has a first end 607 that is coupled to a first fitting 620, (e.g., male fitting) within the cathode base 149. Specifically, the first fluid supply line 608 also includes a second fitting 622 (e.g., female fitting) on an end proximate the cathode base 149. The female fitting 622 is coupled (e.g., threaded) to the male fitting 620 in the cathode base 149. Similarly, a second fluid supply line (not shown) of the pair of fluid supply lines is disposed in the second fluid supply line conduit (not shown) and is coupled in a similar manner to a second fitting (not shown) disposed in the cathode base 149.

A cooling channel 630 passes through the cathode base 149 and the insulative plate 404, and is coupled to one or more cooling passages 632 disposed within the electrostatic chuck 150. In addition, each of the pair of fluid supply lines 608 has a second end 609 that are each coupled to a heat transfer fluid supply 610. The heat transfer fluid supply 610 provides a coolant, such as water, such that the first fluid supply line facilitates providing the cooling fluid, while the second fluid supply line facilitates a return. In this manner, a closed heat exchange system is implemented in the wafer support assembly 148.

In one aspect, the centrally disposed recess 206 functions as a sump. Furthermore, the position of the first end 604 of the first fluid supply line conduit 602 relative to the second end 606 provides a negatively sloped diagonal drainage path should any fluid leaks develop within the support assembly 148, fluid supply lines 602, or other location. The position of the conduits (first and second fluid supply line conduits 602) at the bottom 304 of the recess 206 assists in draining any fluids that may collect in the recess 206 from the support platform 140. In particular, the recess 206 and conduits (first fluid supply line conduit 602 and second fluid supply line conduit) protect the support assembly 148, electrical connection, and other system components that may be susceptible to damage by channeling the undesirable fluids away from the support assembly 148.

FIG. 6 further depicts a cross sectional view of the chamber body 102 having a backside gas supply line 612, taken along section line 6-6 of FIG. 2. The gas supply line 612 is one of a pair of backside gas supply lines (only one gas supply line shown in FIG. 6). The pair of backside gas supply lines provide independent conduits for a heat transfer gas (e.g., helium) from a gas source 614, through a pair of corresponding gas passages 216 disposed in the substrate support assembly 148 (see FIG. 2), to the underside of the wafer 101. Specifically, the gas supply lines 612 each comprise a first end 615 and a second end 616 that extend through one of the support arms, for example, the first support arm 142. The second end 616 of the gas supply lines 612 are coupled to a backside gas supply 614, which is external to the outside surface 124 of the sidewall 122 of the chamber body 102.

The first ends 615 of the gas supply lines 612 are coupled to the gas passages 216 and positioned radially within the inner area of the plurality of lobed o-ring 212, thereby isolating and protecting the gas supply lines 612 and backside gas passages 216 from the processing environment. In particular, the gas passages 216 each have a first end 617 beginning at the wafer support surface 412 of the electrostatic chuck 150, and a second end 618 that are respectively coupled with the first ends 615 of the gas supply lines 612. Thus, each gas passage 216 extends through the electrostatic chuck 150, the insulative plate 404, the cathode base 149, and the first surface 144 of the support platform 140.

An o-ring 626 is provided around the second ends 618 of the gas passages 216 below the first surface 144 of the support platform 140 to prevent gas leakage between the support platform 142 and the support assembly 148. The o-ring 626 is positioned radially inward of the lobed o-ring 212 such that the o-ring 626 is generally not in contact with the processing environment of the processing region 128. Isolating the o-ring 626 from the processing region extends the life of the o-ring 626. A depicted in FIG. 2, the space provided by one of the lobes 218 of the lobed o-ring 212 is utilized to provide room of the gas passages 216 and associated o-rings 626, and effectively couple the backside gas passages 216 to the support assembly 148.

During semiconductor wafer processing, one of the pair of backside gas passages 216 provides the heat transfer gas to the inner portion of the of the support surface 412, while the other gas passage provides the heat transfer gas to the outer portion of the support surface 412. The heat transfer gas, i.e., backside gas, passes through grooves (not shown) located on the top surface of the electrostatic chuck 150 to facilitate heat transfer between the chuck 150 and the substrate 101.

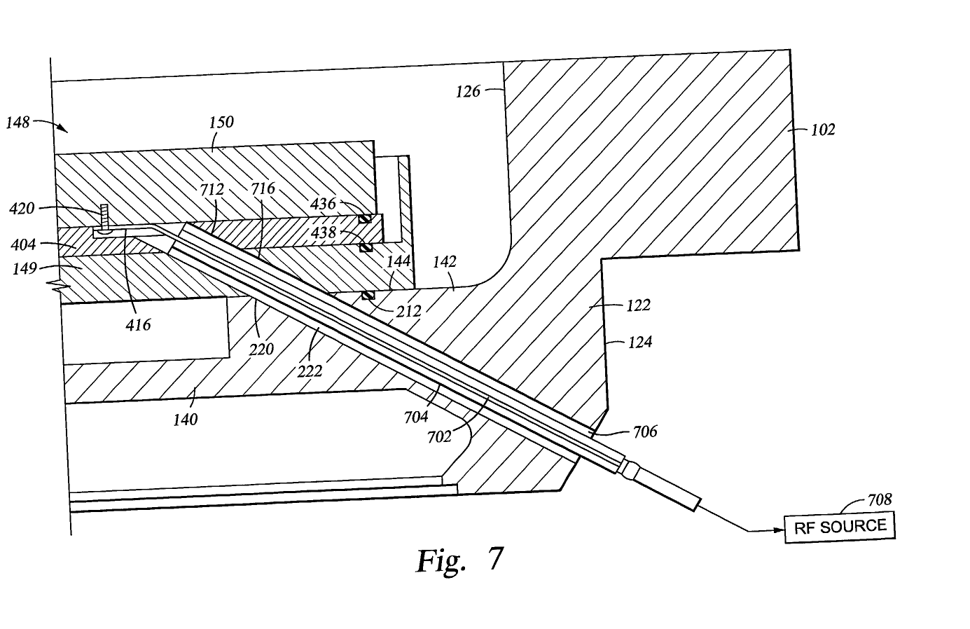

FIG. 7 depicts a cross sectional view of the chamber body having a RF cable taken along section line 7-7 of FIG. 2. The first end 220 of the RF conduit 222 is disposed through the first surface 144 of the support platform 140, the cathode base 149, and insulative plate 404. A second end 706 of the RF conduit 222 is disposed on the outside surface 124 of the sidewall 122 of the chamber body 102 such that the RF conduit 222 passes diagonally with a negative slope through one of the support arms, for example, the first support arm 142.

A RF cable 702 is generally disposed through the RF conduit 222 and through channels 710 and 716 disposed in the cathode base 149 and insulative plate 404, respectively. An insulating sleeve 704 surrounds the RF cable 702 to electrically isolate the RF cable from the chamber body 102, cathode base 149 and insulative plate 404. The RF cable 702 is fabricated from a flexible, conductive material, such as copper. The RF cable 702 may have any number of forms, such as strained cable, wire, solid, strap or bar form. The insulating sleeve 704 is a dielectric material. In one embodiment, the RF cable 702 is a copper strap having a substantially rectangular cross section whereas the insulating sleeve 704 is a fluoropolymer such as TEFLON®.

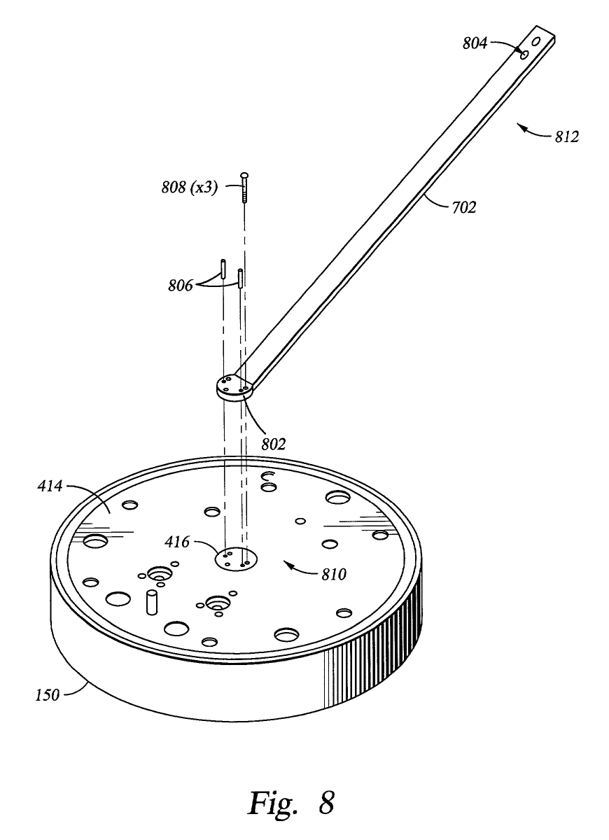

FIG. 8 depicts a perspective view of a bottom of the electrostatic chuck and the RF cable. Specifically, FIG. 8 depicts a perspective view of the second surface 414 of the electrostatic chuck 150 and the RF cable 702 rotated 180°. The RF cable 702 comprises a first end 810 having a contact surface 802, and a second end 812 having two mounting holes 804. The contact surface 802 is substantially flat so that RF power supplied from a RF source 708 is efficiently coupled to the electrode 408 of the electrostatic chuck 150 via the contact pad 416. The ample surface area of the contact surface 802 and contact pad 416 interface discourages arcing between the contact surface 802 and contact pad 416 that may otherwise fuse the two surfaces together. The contact surface 802 and contact pad 416 are orientated using dowel pins 806 to insure alignment of the RF cable 702 with the RF conduit 222. The contact surface 802 and contact pad 416 are secured to one another by a plurality of fasteners 808 such as stainless screws. Other fasteners may be used. Thus, as the RF cable 702 is readily fed through the RF conduit 222 to the second surface 414 of the electrostatic chuck 150, thereby allowing the support assembly 148 to be easily removed from the support platform 140 during system maintenance procedures.

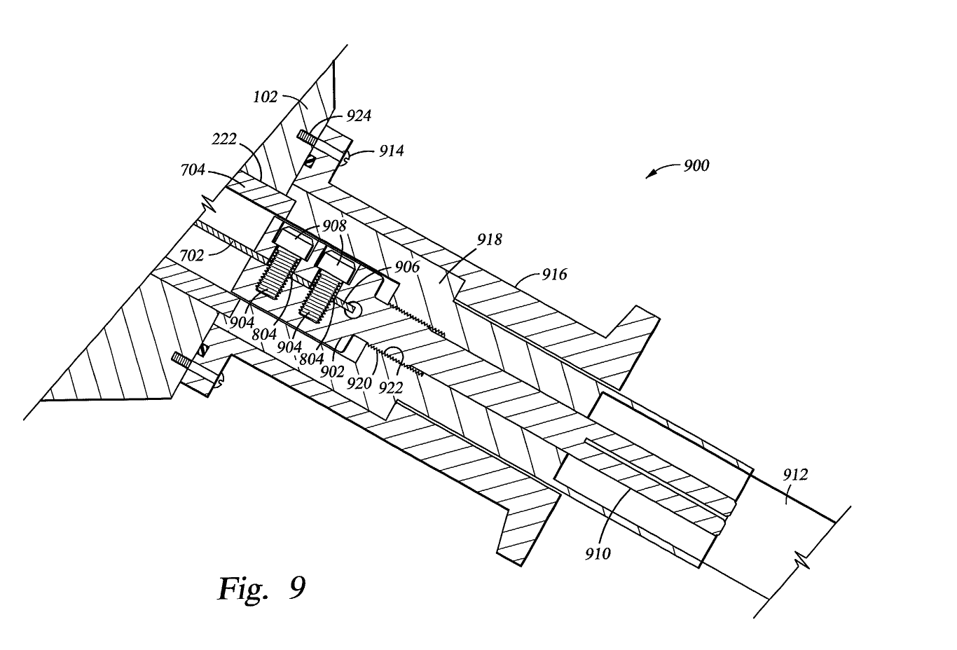

FIG. 9 depicts a cross sectional view of a terminal assembly 900 of the RF cable 702 of FIGS. 7 and 8. The RF cable 702 is coupled to a fitting 902. The fitting 902 is fabricated from a conductive material such as brass or the like. The fitting 902 has two cross-holes 904 that pass through a slot 906 in the fitting 902. The RF cable 702 is disposed in the slot 906 such that the mounting holes 804 align with the fitting cross-holes 904. A fastener 908, such as a bolt fabricated from stainless steel or the like, is threaded into each hole 904, thereby retaining the RF cable 702 in the fitting 902. The fitting 902 has a bifurcated distal end 910 that electrically contacts a conductor 912 that is coupled to the RF source 708.

The conductor 912 has a terminal assembly 900, which includes housing 916 and an insulator bushing 918. The bushing 918 has a threaded portion 920, which mates with a threaded portion 922 of the fitting 902, thereby retaining the conductor 912 to the RF cable 702. The housing 916 surrounds the bushing 918 and is secured to the chamber body 102 via a plurality of fasteners 914 that thread into a threaded hole 924 in the chamber body 102. Thus, the RF cable conduit 222 and cable arrangement provides easy removal of the chuck 150, while decreasing the risks of breaking the cable 702 or damaging the electrostatic chuck 150 at the contact surface 802.

Although the teachings of the present invention that have been shown and described in detail herein, those skilled in the art can readily devise other varied embodiments that still incorporate the teachings and do not depart from the spirit of the invention.

What is claimed is:

1. A semiconductor wafer processing chamber, comprising:
a substrate support platform having a centrally disposed recess;
a substrate support assembly disposed over said centrally disposed recess of said support platform;
at least one platform arm extending radially from the substrate support platform to a sidewall of said processing chamber; and
at least one process chamber equipment conduit disposed diagonally to define a negative slope, through the at least one platform arm.

2. The processing chamber of claim 1 wherein said substrate support assembly comprises:
a cathode base disposed above said centrally disposed recess;
an insulative plate coupled to said base; and
a substrate support coupled to said insulative plate.

3. The processing chamber of claim 1 wherein said centrally disposed recess is defined by a plurality of walls extending from a first surface of said support platform to a bottom of said support platform.

4. The processing chamber of claim 2 wherein said substrate support comprises at least one chucking electrode embedded therein.

5. The processing chamber of claim 4 wherein said a least one process chamber equipment conduit comprises a RF cable conduit.

6. The processing chamber of claim 5 wherein said RF cable conduit comprises:
a first end, said first end of said RF cable conduit axially aligned with a base slot disposed in said base and a insulative plate slot disposed in said insulative plate; and
a second end disposed proximately an outside surface of a sidewall of said processing chamber wherein said RF cable conduit, said base slot, and said insulative plate slot form a RF cable channel.

7. The processing chamber of claim 6 wherein the first end of said RF cable conduit is positioned higher than the second end of said RF cable conduit.

8. The processing chamber of claim 6 further comprising an RF cable disposed through said RF cable conduit, said base slot and said insulative plate slot, said RF cable having a first end coupled to said at least one chucking electrode and a second end coupled to a fitting external to an outer surface of said processing chamber.

9. The processing chamber of claim 8 wherein said RF cable further comprises an insulating sleeve surrounding said RF cable to electrically isolate said RF cable from said processing chamber.

10. The processing chamber of claim 8 wherein said first end of said RF cable comprises a flat contact surface area coupled to a contact pad of said at least one chucking electrode.

11. The processing chamber of claim 10 wherein said flat contact surface area of said first end of said RF cable and said contact pad of said at least one chucking electrode are orientated for insuring alignment of the RF cable within the RF cable conduit.

12. The processing chamber of claim 11 wherein said flat contact surface area comprises a bore extending therethrough for receiving a dowel pin.

13. The apparatus of claim 8 wherein said fitting further comprises at least one bore axially aligned with at least one second end bore in said second end of said RF cable for respectively receiving at least one fastener.

14. The processing chamber of claim 13 wherein said RF cable further comprises:
an insulator bushing disposed over and circumscribing said fitting; and
a housing disposed over said insulator bushing and adapted for coupling to said outer surface of said processing chamber.

15. The processing chamber of claim 3 wherein said a least one process chamber equipment conduit further comprises at least one backside gas supply line conduit.

16. The processing chamber of claim 15 wherein said at least one backside gas supply line conduit has a first end disposed in one of said plurality of walls of said centrally disposed recess, and a second end disposed on said outside surface of said processing chamber.

17. The processing chamber of claim 16 further comprising at least one backside gas supply line having a first and second end, said backside gas supply line respectively disposed through said at least one gas supply line conduit, wherein said first end is coupled to a respective gas passage, and said second end is adapted for connection to a backside gas source.

18. The processing chamber of claim 17 wherein said gas passage passes through said base, said insulative plate, and said substrate support.

19. The processing chamber of claim 3 wherein said a least one process chamber equipment conduit further comprises a pair of fluid line conduits.

20. The processing chamber of claim 19 wherein said pair of fluid supply line conduits have a first fluid supply conduit end disposed in one of the plurality of walls of said centrally disposed recess, and a second fluid supply conduit end disposed proximate said outside surface of said processing chamber.

21. The processing chamber of claim 20 wherein at least a portion of said first fluid supply conduit end intersects with said bottom of said centrally disposed recess.

22. The processing chamber of claim 21 further comprising a pair of fluid supply lines extending through said pair of fluid supply line conduits, said pair of fluid supply lines comprising a first fluid supply line end coupled to said cathode base, and a second fluid supply line end adapted for connection to a fluid supply, wherein a heat transfer fluid circulates within said substrate support assembly.

23. The processing chamber of claim 3 wherein said at least one process chamber equipment conduit further comprises a temperature probe cable conduit.

24. The processing chamber of claim 23 further comprising a temperature probe cable disposed through said temperature probe cable conduit, said temperature probe cable having a first end coupled to a temperature sensor disposed in said substrate support assembly, and a second end adapted for connection to a temperature controller.

25. The processing chamber of claim 3 further comprising a pumping stack welded to a second surface and communicating with an exhaust passage defined beneath said substrate support platform.

26. The processing chamber of claim 25 wherein said pumping stack is welded via an electron beam weld to said chamber body.

27. The processing chamber of claim 26 wherein said pumping stack is welded via a plurality of tack welds to said chamber body.

28. The processing chamber of claim 25 wherein said pumping stack comprises:
a throttle valve assembly;
a gate valve coupled to said throttle valve assembly; and
a pump coupled to said gate valve.

29. The processing chamber of claim 28 wherein said throttle valve assembly is welded via an electron beam weld to said second surface of said processing chamber.

30. The processing chamber of claim 29 wherein said throttle valve assembly is welded via a plurality of tack welds to said second surface of said processing chamber.
